(19) United States
(12) Patent Application Publication
(10) Pub. No.: US 2010/0167507 A1
(43) Pub. Date: Jul. 1, 2010

(54) PLASMA DOPING APPARATUS AND PLASMA DOPING METHOD

(75) Inventors: Masahiro Horigome, Yamanashi (JP); Yoshihiro Ishida, Yamanashi (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/601,993

(22) PCT Filed: May 13, 2008
(86) PCT No.: PCT/JP2008/058778

§ 371 Date: Nov. 25, 2009

(30) Foreign Application Priority Data
May 31, 2007 (JP) 2007-146034

(51) Int. Cl. H01L 21/306; C23C 16/513; C23C 16/511; C23C 16/52

(52) U.S. Cl. 438/513; 118/723 R; 118/723 AN; 118/697; 257/E21.215

(57) ABSTRACT

A plasma doping apparatus implants an impurity element into a surface of a processing target object W by using plasma. The apparatus includes a high frequency power supply 72 configured to supply a high frequency bias power to a mounting table 34 installed within a processing chamber 32; a gas feed unit 96 configured to supply a doping gas containing an impurity element into the processing chamber 32; and a plasma generation unit 78 configured to generate the plasma within the processing chamber 32. In accordance with this apparatus, a portion doped with the impurity element can be made very thin, and the impurity element can be rapidly doped in a high concentration.

### TECHNICAL FIELD

The present invention relates to a plasma doping apparatus and a plasma doping method for doping an impurity element into a surface of a processing target object such as a semiconductor wafer by using plasma.

### BACKGROUND ART

In general, an ion implanter is used to dope an impurity element in a manufacturing process of a semiconductor device (see, for example, Patent Documents 1 and 2). The ion implanter has many advantages in that it is capable of precisely controlling the impurity element and carrying out the process while checking the number of ions. In the ion implanter, a gas of halogen compounds or the like is excited into a plasma state and ions are taken out by applying an electric field by an electrode installed on ions' way. Then, a mass spectrometry is conducted to extract certain ions while excluding impurity ions by way of applying a preset magnetic field to a taken-out ion beam. Then, the extracted ions are doped into the processing target object while energy of the ions is controlled.

Here, an example of a semiconductor device manufactured by the doping of the impurity element will be explained. FIG. 1 is a schematic diagram of a MOSFET (Metal Oxide Semiconductor Field Effect Transistor) which is an example semiconductor device. The MOSFET has a P-type or N-type well 2 formed in a surface of a semiconductor wafer W made of a silicon substrate. A gate electrode 6 made of, e.g., an impurity-doped polysilicon film is formed on a surface portion of the well 2 via a gate insulating film 4. A gate wiring 8 made of, e.g., an aluminum alloy is formed on the gate electrode 6. Sidewalls 10 made of, e.g., a silicon nitride film are formed on both sides of the gate electrode 6.

A source 12 and a drain 14 made of, e.g., an impurity-doped polysilicon are respectively formed below the both sides of the gate electrode 6, and a source wiring 16 and a drain wiring 18 made of, e.g., an aluminum alloy are respectively formed on the gate electrode 6. Further, extension portions 20 made of, e.g., an impurity-doped polysilicon are respectively formed between the source 12 and the drain 14 below the sidewalls 10 so as to prevent a short-channel effect.

The extension portions 20 are thinner (shallower) than the source 12 and the drain 14, while an impurity element concentration of the extension portions 20 is lower than those of the source 12 and the drain 14. A transistor structure having the above-described extension portions 20 is referred to as a LDD (Lightly-Doped Drain) structure.

To form the source 12, the drain 14 and the extension portions 20, an impurity element is first doped into regions corresponding to the source 12, the drain 14 and the extension portions 20 shallowly in a low concentration by using the ion implanter after the gate electrode 6 is formed on the gate insulating film 4. Then, after the sidewalls 10 are formed, the impurity element is doped more deeply in a higher concentration, so that the source 12 and the drain 14 are respectively formed. In this second doping process, the sidewalls 10 serve as a mask for the extension portions 20.

Patent Document 1: Japanese Patent Laid-open Publication No. H4-319243
Patent Document 2: Japanese Patent Laid-open Publication No. H5-251033

### DISCLOSURE OF THE INVENTION

### Problems to Be Solved by the Invention

However, to meet a recent demand for a higher level of integration and miniaturization of the semiconductor device, a wiring width or a film thickness needs to be further scaled down. Accordingly, a design rule of the semiconductor device is getting finer. Under such circumstance, a thickness of, e.g., the extension portions 20 needs to be further reduced (thinned), while a concentration of the impurity elements needs to be increased.

To dope the impurity element more shallowly in a high concentration, the ions need to be doped with a low energy by the ion implanter. In consideration of the performance of the ion implanter, however, a beam current is extremely reduced when it is operated in a low energy state. Accordingly, it takes an excessively long time to complete the doping of the impurity element until a required high concentration is achieved, which in turn results in a great reduction of throughput.

To describe the aforementioned phenomenon, FIG. 2 provides a graph showing a relationship between an implant energy (doping energy), a beam current and an implant time (doping time). FIG. 2 illustrates an example case in which B (boron) as the impurity element is doped on a wafer having a diameter of 200 mm in a dose of about 1.0×10¹⁵ ions/cm². The implant energy needs to be reduced so as to implant and dope the impurity element shallowly. If, however, the implant energy is reduced, the beam current is also reduced. As illustrated in FIG. 2, if the beam current is further reduced, the implant time taken to dope the impurity element up to the preset dose would be rapidly increased.

This phenomenon implies that a very long time is required to implant and dope the impurity element into a shallow or a thin portion such as the extension portions 20 up to a high concentration, resulting in a deterioration of throughput.

Moreover, if the ions are radiated at a low energy, a diameter of an ion beam is increased and the ions are diffused. Thus, since a distance from an ion source to the wafer is very long in the ion implanter as described above, a part of the diffused ions may collide with various materials constituting the ion implanter on ion's way, thus causing a metal contamination or a particle generation.

In view of the foregoing, the present invention provides a plasma doping apparatus and a plasma doping method capable of rapidly doping an impurity element into a surface of a processing target object very thinly in a high concentration, thus improving a throughput.

### Means for Solving the Problems

In accordance with one aspect of the present invention, there is provided a plasma doping apparatus that implants an impurity element into a surface of a processing target object by using plasma, the apparatus including: a processing chamber; a mounting table installed in the processing chamber and configured to mount the processing target object thereon; a high frequency power supply that applies a high frequency bias power to the mounting table; a gas feed unit that supplies a gas containing a doping gas having an impurity element into the processing chamber; and a plasma generation unit that generates the plasma within the processing chamber.

In the above-stated plasma doping apparatus, it is desirable that the plasma generation unit includes a planar antenna member installed outside the processing chamber; a microwave generator that generates a microwave; and a waveguide configured to propagate the microwave to the planar antenna member. Further, it is desirable that the gas feed unit includes a doping gas feed unit that supplies the doping gas; and a plasma stabilizing gas feed unit that supplies a plasma stabilizing gas for stabilizing the plasma. Furthermore, it is desirable that the doping gas feed unit has a shower head structure in which a plurality of gas discharge holes is provided at a gas flow path formed in a lattice shape.

Further, the plasma stabilizing gas feed unit may be installed opposite to the mounting table across the doping gas feed unit. The plasma stabilizing gas feed unit may include a gas flow path installed along a sidewall of the processing chamber, and the gas flow path may be provided with a multitude of gas discharge holes.

It is desirable that a frequency of the high frequency bias power is set to be in the range of about 400 kHz to about 13.56 MHz. It is desirable that an ion energy attracted by the high frequency bias power is set to be in the range of about 100 to about 1000 eV.

Further, in accordance with another aspect of the present invention, there is provided a plasma doping method for doping an impurity element contained in a doping gas into a surface of a processing target object, which is mounted on a mounting table within a processing chamber, by using plasma, the method including: applying a high frequency bias power to the mounting table; generating the plasma by supplying the doping gas into the processing chamber; and doping the impurity element into the surface of the processing target object by attracting the impurity element in the doping gas by the high frequency bias power.

In the above-stated plasma doping method, it is desirable that a frequency of the high frequency bias power is set to be in the range of about 400 kHz to about 13.56 MHz. Further, it is desirable that an ion energy attracted by the high frequency bias power is set to be in the range of about 100 to about 1000 eV. An extension portion of a MOSFET may be formed by doping the impurity element.

In accordance with still another aspect of the present invention, there is provided a storage medium that stores therein a computer-readable program for controlling an operation of a plasma doping apparatus that dopes an impurity element contained in a doping gas into a surface of a processing target object, which is mounted on a mounting table within a processing chamber, by using plasma. The computer-readable program controls the plasma doping apparatus to generate the plasma by applying a high frequency bias power to the mounting table and supplying the doping gas into the processing chamber; and to dope the impurity element into the surface of the processing target object by attracting the impurity element in the doping gas by the high frequency bias power.

The above and other objects and features of the present invention will become apparent from the following description of the embodiments given in conjunction with the accompanying drawings.

### EFFECT OF THE INVENTION

In accordance with the plasma doping apparatus and the plasma doping method of the present invention, since the impurity element is doped into the surface of the processing target object on the mounting table by attracting the ions of the impurity element by the high frequency bias power after the plasma is generated in the processing chamber, a doped portion can be made very thin, and the impurity element can be rapidly doped in a high concentration. Thus, throughput can be improved.

### BRIEF DESCRIPTION OF THE DRAWINGS

FIG. 1 is an enlarged schematic view of a MOSFET as an example semiconductor device.

FIG. 2 is a graph showing a relationship between an implant energy, a beam current and an implant time.

FIG. 3 is a configuration view of a plasma doping apparatus in accordance with the present invention.

FIG. 4 is a plane view of a doping gas feed unit having a shower head structure.

FIG. 5 provides a graph showing a relationship between a waveform of a high frequency bias power and ion doping.

FIG. 6 is a graph showing a relationship between a bias power (ion energy) and a concentration profile of ions doped into a wafer surface in an implantation depth direction.

FIG. 7 presents a graph showing a plasma potential in a processing space of the plasma doping apparatus.

FIG. 8 is a plane view showing a part of a planar antenna structure used in investigation of charge-up damage.

FIG. 9 is a graph showing an ion current along a wafer surface direction in the plasma doping apparatus.

### EXPLANATION OF CODES

30: Plasma doping apparatus
32: Processing chamber
33: Mounting table
60: Heating unit
72: High frequency bias power supply
78: Plasma generation unit
80: Planar antenna member
80a: Slots
88: Coaxial waveguide
92: Rectangular waveguide
94: Microwave generator
96: Gas feed unit
98: Doping gas feed unit
100: Plasma stabilizing gas feed unit
102: Gas flow paths
102a: Gas discharge holes
104: Gas flow path
104a: Gas discharge holes
110: Controller
112: Storage medium
W: Semiconductor wafer (processing target object)

### BEST MODE FOR CARRYING OUT THE INVENTION

Hereinafter, a plasma doping apparatus and a plasma doping method in accordance with an embodiment of the present invention will be described with reference to the accompanying drawings.

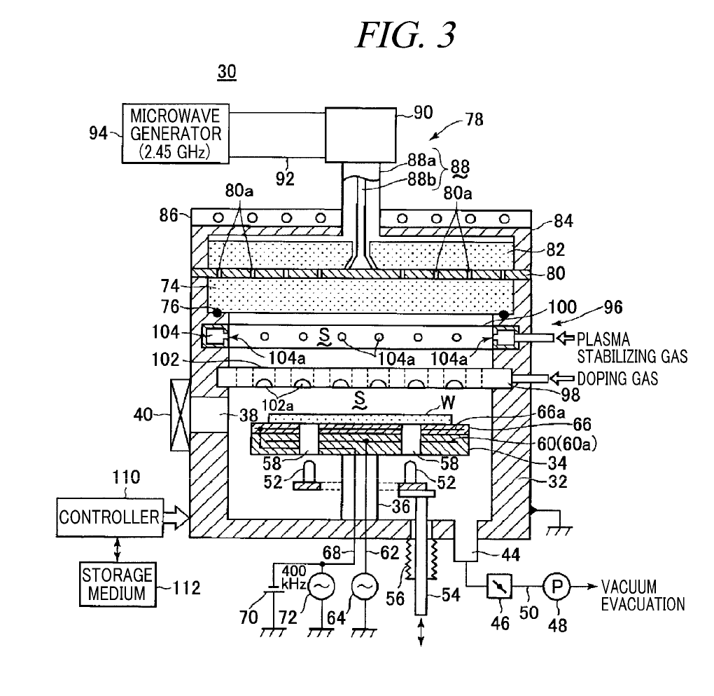

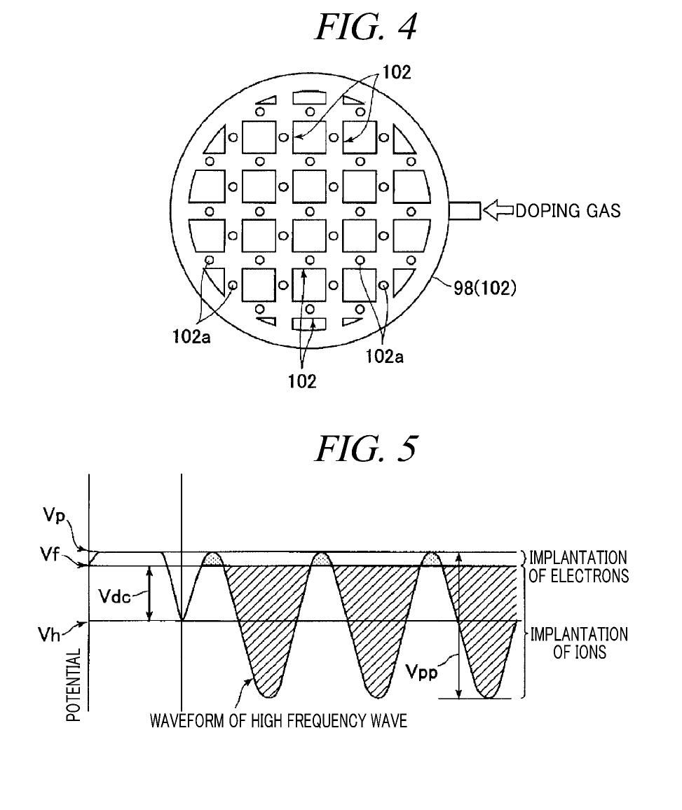

FIG. 3 is a diagram showing an overall configuration of the plasma doping apparatus in accordance with the embodiment of the present invention. FIG. 4 is a plane view of a doping gas feed unit of a shower head structure shown in FIG. 3. The plasma doping apparatus illustrated in FIG. 3 employs a RLSA (Radial Line Slot antenna) type planar antenna.

As illustrated in FIG. 3, the plasma doping apparatus 30 includes a cylindrical processing chamber 32 having, for example, a sidewall or a bottom made of a conductor such as an aluminum alloy. A hermetically sealed processing space S is provided within the processing chamber 32, and plasma is generated in this processing space S. The processing chamber 32 is grounded.

A mounting table 34 configured to mount a processing target object, e.g., a semiconductor wafer W, on a top surface thereof is accommodated in the processing chamber 32. The mounting table 34 is made of a ceramic material such as alumina in a substantially circular flat plate shape. The mounting table 34 is installed at the bottom of the processing chamber 32 by a supporting column 36 made of, e.g., aluminum.

An opening 38 is provided in a sidewall of the processing chamber 32, and a gate valve 40, which is opened and closed when the wafer is loaded into or unloaded from the inside of the processing chamber 32, is installed at the opening 38. Further, a gas exhaust port 44 is provided in the bottom of the processing chamber 32, and a gas exhaust path 50 having a pressure control valve 46 and a vacuum pump 48 is coupled to the gas exhaust port 44. When necessary, by exhausting the gas from the processing chamber 32 through the gas exhaust path 50, a preset pressure can be maintained within the processing chamber 32.

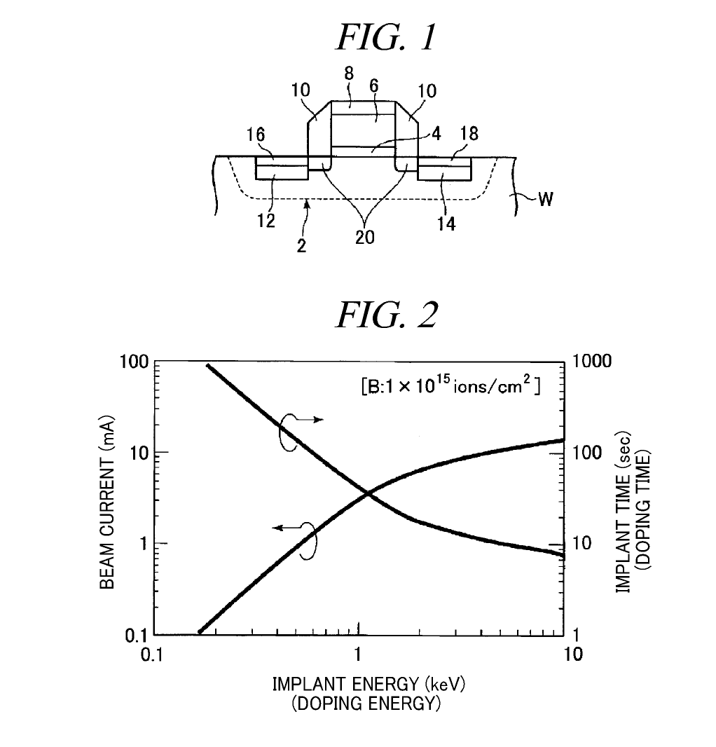

A plurality of, e.g., three elevating pins 52 (only two of them are illustrated in FIG. 1) are installed below the mounting table 34 to lift up and down the wafer W when the wafer W is loaded or unload. The elevating pins 52 are vertically movable by an elevation rod 54 which is installed in such a manner as to penetrate the bottom of the processing chamber 32. An expandable/contractible bellows 56 is installed at a portion where the elevation rod 54 penetrates the bottom of the processing chamber 32, whereby the vertical movement of the elevation rod 54 can be performed while airtightness is maintained. The mounting table 34 is provided with pin insertion through holes 58 through which the elevating pins 52 are inserted.

The entire mounting table 34 is made of a heat resistant material, e.g., ceramic such as alumina. A heating unit 60 is installed within the mounting table 34. The heating unit 60 includes a thin-plate-shaped resistance heater 60a buried in the substantially entire region of the mounting table 34. The resistance heater 60a is connected to a heater power supply 64 via a wiring 62 extended through the inside of the supporting column 36. Such a heating unit may not be installed when the heating of the wafer W is not necessary.

An electrostatic chuck 66 having a chuck electrode 66a formed in, e.g., a mesh shape is installed within a top surface portion of the mounting table 34. The electrostatic chuck 66 attracts and holds the wafer W mounted on the mounting table 34 by an electrostatic attracting force. The chuck electrode 66a of the electrostatic chuck 66 is connected to a DC power supply 70 via a wiring 68 to generate the electrostatic attracting force. Further, a high frequency bias power supply 72 is coupled to the wiring 68 to apply a high frequency bias power of, e.g., about 400 kHz to the chuck electrode 66a during a plasma process. With this configuration, ions in the processing space S can be attracted toward the mounting table 34 as will be discussed later.

A ceiling portion of the processing chamber 32 is opened, and a top plate 74 made of a ceramic material such as Al₂O₃ is hermetically installed at the opening portion via a sealing member 76 such as an O ring. The top plate 74 has a transmissive property with respect to a microwave. A thickness of the top plate 74 is set to be, e.g., about 20 mm in consideration of pressure resistance.

A plasma generation unit 78 for generating plasma within the processing chamber 32 is installed on a top surface of the top plate 74. To elaborate, the plasma generation unit 78 includes a circular-plate-shaped planar antenna member 80 installed on the top surface of the top plate 74, and a wavelength shortening member 82 is installed on the planar antenna member 80. The wavelength shortening member 82 is made of, e.g., aluminum nitride having a high-k property to shorten a wavelength of a microwave, and the planar antenna member 80 serves as a bottom plate of a waveguide box 84 serving as a hollow conductive cylinder-shaped container that encloses the entire top surface of the wavelength shortening member 82. A cooling jacket 86 configured to flow a coolant therein is installed on the waveguide box 84.

An external tube 88a of the coaxial waveguide 88 is coupled to a center of the waveguide box 84. An internal conductor 88b inside the waveguide box 84 is coupled to a central portion of the planar antenna member 80 through a through hole formed in the center of the wavelength shortening member 82. The coaxial waveguide 88 is connected to a microwave generator 94 of, e.g., about 2.45 GHz via a rectangular waveguide 92 having a mode converter 90 and a matcher (not shown) and is capable of propagating a microwave to the planar antenna member 80. A frequency of the microwave is not limited to 2.45 GHz, but a frequency of, e.g., about 8.35 GHz, may be utilized instead.

When a wafer having a diameter of about 300 mm is used, the planar antenna member 80 is configured as a circular plate having a diameter of, e.g., about 400 to about 500 mm and a thickness of, e.g., about 1 to about 3 mm. The planar antenna member 80 is made of a conductive material such as copper or aluminum, and its surface is plated with, e.g., silver. Further, the planar antenna member 80 is provided with a number of slots 80a, each of which is formed of an elongated groove-shaped through hole. The arrangement of the slots 80a is not particularly limited, and the slots may be arranged in, e.g., a concentric circular shape, a spiral shape, a radial shape, or any shape uniformly distributed across the entire surface of the antenna member. The planar antenna member 80 has a so-called RLSA (Radial Line Slot Antenna) type antenna structure, so that high-density plasma having a low electron temperature can be obtained.

Installed above the mounting table 34 is a gas feed unit 96 for supplying a gas containing a doping gas having an impurity element into the processing chamber 32 while controlling a flow rate thereof. The gas feed unit 96 includes a doping gas feed unit 98 installed directly above the mounting table 34, for supplying the doping gas; and a plasma stabilizing gas feed unit 100 for supplying a plasma stabilizing gas for stabilizing the plasma generated in the processing space S. As illustrated in FIG. 2, the doping gas feed unit 98 has a so-called shower head structure in which gas flow paths 102 including, e.g., pipes are formed in a lattice shape, and a multiple number of gas discharge holes 102a are provided in bottom surfaces of the gas flow paths 102.

With such a shower head structure, the doping gas can be uniformly supplied to the substantially entire surface of the processing space S. The entire doping gas feed unit 98 is made of, e.g., quartz or an aluminum alloy. The doping gas is selected depending on the impurity element to be doped, and BF₃, B₂H₄, PH₃, AsH₅ or the like may be used as the doping gas, for example. The doping gas may be supplied alone or together with a rare gas such as an Ar gas.

The plasma stabilizing gas feed unit 100 has a ring-shaped gas flow path 104 installed along a sidewall of the processing chamber 32 above the doping gas feed unit 8 and below the top plate 74. A plurality (multitude) of gas discharge holes 104a is provided in an inner sidewall of the gas flow path 104 at a certain distance along a circumferential direction thereof, whereby the plasma stabilizing gas can be supplied toward a center of the processing space S. The entire gas flow path 104 may be made of, e.g., quartz or an aluminum alloy. A rare gas such as Ar, He, or Xe may be used as the plasma stabilizing gas.

The overall operation of the plasma doping apparatus 30 configured as described above is controlled by a controller 110 made up of, e.g., a computer. A computer program for executing the operation is stored in a storage medium 112 such as a flexible disk, a CD (Compact Disk), a hard disk, or a flash memory. Specifically, a supply or a flow rate of each gas, a supply or a power of the microwave or high frequency wave, a processing temperature, a processing pressure, and the like are controlled in response to instructions from the controller 110.

Now, a plasma doping method, which is performed by the plasma doping apparatus 30, will be explained.

First, a semiconductor wafer W is loaded into the processing chamber 32 by a transfer arm (not shown) via the gate valve 40, and the wafer W is then placed on a mounting surface on a top surface of the mounting table 34 by moving the elevating pins 52 up and down. Then, the wafer W is electrostatically attracted and held by the electrostatic chuck 66.

The wafer W is heated up to a preset processing temperature by the heating unit 60 of the mounting table 34 and maintained at the processing temperature. Then, the doping gas containing the impurity element is supplied from the doping gas feed unit 98 of the gas feed unit 96 while its flow rate is controlled. The doping gas is discharged from the gas discharge holes 102a formed at the lattice-shaped gas flow paths 102 into the entire region of the processing space S in a substantially uniform manner. Meanwhile, the plasma stabilizing gas is supplied from the plasma stabilizing gas feed unit 100 while its flow rate is controlled. The plasma stabilizing gas is discharged toward the central portion of the processing space S from the gas discharge holes 104a formed at the ring-shaped gas flow path 104 installed along the chamber sidewall.

A vacuum exhaust system maintains the inside of the processing chamber 32 at a preset processing pressure by way of controlling the pressure control valve 46. At the same time, the microwave generator 94 of the plasma generation unit 78 is driven, so that a microwave generated from the microwave generator 94 is supplied to the planar antenna member 80 via the rectangular waveguide 92 and the coaxial waveguide 88. The microwave whose wavelength is shortened by the wavelength shortening member 82 is then introduced into the processing space S. As a result, plasma is generated in the processing space S, and a doping process using the plasma is carried out. At this time, a high frequency bias power is applied from the high frequency bias power supply 72 to the chuck electrode 66a of the electrostatic chuck 66 installed in the mounting table 34, whereby ions of the impurity element are attracted.

As stated above, by applying the high frequency bias power of, e.g., about 400 kHz to the mounting table 34, the ions of the impurity element, e.g., As, are attracted into the surface of the wafer W and doped therein. Here, since the plasma is excited in the processing chamber 32 by the microwave introduced from the planar antenna member 80 having the RLSA structure, the plasma may have a low electron temperature and a high density while it is distributed uniformly. Accordingly, the impurity element can be rapidly doped into the surface wafer with a high uniformity. Here, as stated above, a rare gas such as Ar or Xe is used as the plasma stabilizing gas. Further, the doping gas is selected depending on the impurity element to be doped, and BF₃, B₂H₄, PH₃, AsH₅ or the like may be used, for example. As a result, B (boron), P (phosphorous), As (arsenic), or the like is doped as the impurity element.

Further, the frequency of the high frequency bias power may be desirably in the range of about 400 kHz to about 13.56 MHz. If the frequency is smaller than 400 kHz, the energy of the doped ions may be distributed over a wide range, which is deemed to be undesirable. Meanwhile, if the frequency is larger than 13.56 MHz, the ions of the impurity element may not follow-up an oscillation speed of such a high frequency, thus making it difficult to carry out the doping of the ions.

The ion energy of the impurity element attracted by the high frequency bias power may desirably range from about 100 to about 1000 eV. If the ion energy is smaller than 100 eV, the ions may not be doped. Meanwhile, if the ion energy is larger than 1000 eV, it becomes difficult to carry out a desired shallow and high-density ion implantation of the impurity element because the ions may be implanted deep into the wafer W from the surface thereof.

Here, a principle of doping the impurity element ions using the plasma will be described with reference to a waveform of a high frequency bias power. FIG. 5 is a graph showing a relationship between the waveform of the high frequency bias power and ion doping. In FIG. 5, Vp represents a plasma potential; Vf, a floating potential; Vh, a DC potential of a high frequency electrode (mounting table); Vdc, a difference between the floating potential and the DC potential of the high frequency electrode; and Vpp, a peak-to-peak voltage of the high frequency bias power. The floating potential is generated in the plasma space so as to allow the total amounts of electrons and ions introduced into the high frequency electrode to be same. The floating potential is slightly lower than the plasma potential.

As set forth above, the high frequency bias power oscillates at a frequency of, e.g., about 400 kHz. When the high frequency power is equal to or greater than the floating potential (stipple parts), electrons are implanted into the wafer, whereas when the high frequency power is smaller than the floating potential (slanting line parts), ions are implanted. In this way, implantation (doping) of the electrons and implantation (doping) of the ions take place alternately. During the ion implantation, the above-mentioned impurity element such as B, P or As is doped. Thus, it may be desirable to set the ion implantation period to be as long as possible.

In accordance with the present invention as discussed above, by generating the plasma within the evacuable processing chamber 32 and attracting the ions of the impurity element by the high frequency bias power, the impurity element is doped into the surface of the semiconductor wafer W as the processing target object, placed on the mounting table 34. Accordingly, an impurity element-doped portion can be formed very shallowly or thinly, and since the impurity element can be rapidly doped in a high concentration state, throughput can be improved.

Moreover, in a conventional ion implanter, a diffusion of an ion beam may lead to a particle generation or metal contamination due to a collision of a part of the ion beam against an apparatus constituent member. In the present invention apparatus, however, since the ions are directly attracted to the wafer, the particle generation or the metal contamination can be prevented.

The present inventor has conducted an experiment for doping the impurity element by using the above-described plasma doping apparatus, and investigation results thereof will be explained below.

<Dependency of an Ion Concentration Profile in an Implantation Depth Direction Upon a Bias Power (Ion Energy)>

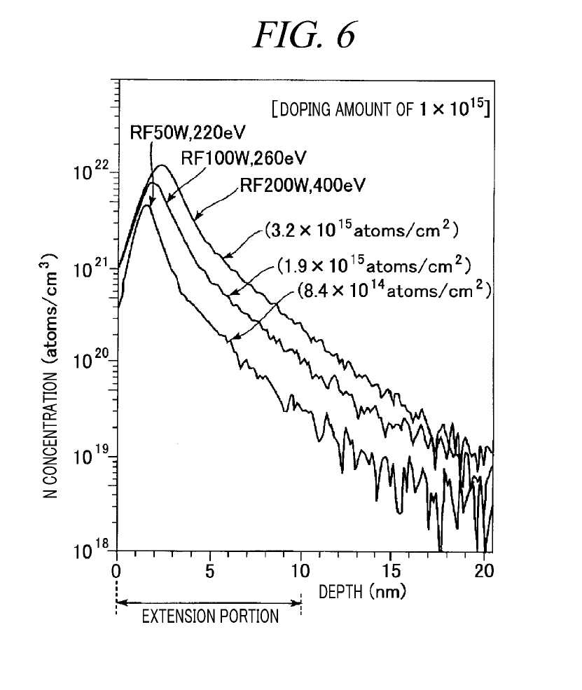

First, a relationship between a bias power (ion energy) and a concentration profile of ions doped into the wafer surface in an implantation depth direction was investigated. FIG. 6 is a graph showing an investigation result.

The high frequency bias power RF was set to be about 50 W (watt), about 100 W and about 200 W, respectively. Ion energies corresponding to the respective watt values were 220 eV, 260 eV and 400 eV, respectively. “N (nitrogen)” was used as the impurity element and was doped for 5 seconds. The nitrogen (N) has been generally used instead of B, As, P, or the like so as to investigate a concentration profile. As for B, As, P or the like, it is known that a peak of a Gaussian distribution profile is slightly shifted from those shown in FIG. 6 to the right of the figure. A thickness (depth) of the extension portion of the MOSFET was up to about 10 nm from the wafer surface.

As clearly seen from the graph shown in FIG. 6, the peak of the N concentration is sequentially shifted to the right and gradually increased as the high frequency bias power increases from about 50 W to about 100 W and about 200 W in sequence. Furthermore, each peak is observed at a depth shallower than 10 nm which is the thickness (depth) of the extension portion. Thus, it was proved that the high-concentration impurity element can be doped in such a shallow portion. In this case, a dose of the impurity element was about 8.4×10¹⁴ atoms/cm², about 1.9×10¹⁵ atoms/cm², and about 3.2×10¹⁵ atoms/cm² when the high frequency power was 50 W (220 eV), 100 W (260 eV) and 200 W (400 eV), respectively.

Accordingly, it was proved that a dose of about 1×10¹⁵ atoms/cm² can be obtained in a short doping time of 5 seconds if the ion energy is larger than about 220 eV. Moreover, it is expected from the graph that if the ion energy increases over 1000 eV, the peak of the N concentration would be observed at a depth of about 10 nm or more. Accordingly, ion energy larger than 1000 eV is deemed to be undesirable in forming the above-described extension portions.

<Investigation of Metal Contamination>

Subsequently, the present inventor has conducted an experiment upon metal contamination of the plasma doping apparatus in accordance with the present invention and investigated the experiment. The investigation result will be discussed below.

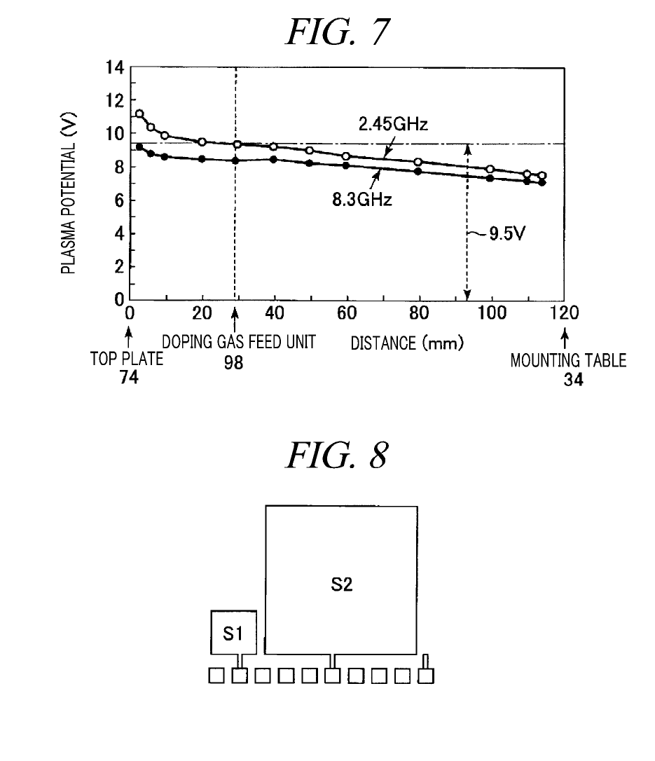

FIG. 7 is a graph showing plasma potential states in the processing space S. A horizontal axis of the graph indicates a distance from the top plate 74 to the mounting table 34, and a vertical axis represents a plasma potential. A radius of the processing chamber was set to be about 150 mm, and a frequency of the microwave from the microwave generator 94 was set to be about 2.45 GHz and about 8.3 GHz, respectively.

When the frequency of the microwave is about 2.45 GHz, a plasma potential near the top plate 74 is about 11 V, and it rapidly decreases to about 10 V at a position slightly distanced from the top plate 74. Then, the plasma potential gently decreases in a substantially straight line shape when approaching the mounting table 34, and is finally reduced to about 8 V at a position slightly above the mounting table 34.

When the frequency of the microwave is about 8.3 GHz, the plasma potential near the top plate 74 is about 9 V, and it gently decreases in a substantially straight line shape as a position is distanced apart from the top plate 74. Finally, it is reduced to about 7 V at a position slightly above the mounting table 34.

A threshold value of the ion energy for triggering sputtering of cobalt (Co), which is most easily sputtered among all metals, is about 12.5 eV. The plasma potential in the all region within the above-described processing space S is smaller than 12.5 eV. Especially, a plasma potential at an installation position of the shower-head-structured doping gas feed unit 98, which is highly likely to be a sputtering target, is about 9.5 eV or less.

From the above-stated investigation result, it is proved that metal contamination or particle generation due to sputtering can be suppressed almost completely.

<Investigation of Charge-Up Damage>

The present inventor also conducted an experiment upon charge-up damage of the plasma doping apparatus in accordance with the present invention. Below, an investigation result thereof is described.

FIG. 8 is a plane view showing a part of a planar antenna structure of a TEG (Test Element Group) utilized in the investigation of the charge-up damage. Planar antennas having various antenna ratios are formed on a wafer surface, and it was investigated whether a dielectric breakdown occurred in the planar antennas due to a charge-up. Here, an antenna ratio refers to a ratio S2/S1 of antenna areas S1 and S2 illustrated in FIG. 8.

In a plasma doping process, a high frequency bias power was set to be about 300 W (ion energy: about 620 eV), and the antenna ratio was set to be about 1 M (1×10⁶), about 100 k (100×10³), about 10 k (10×10³), about 1 k (1×10³), about 100, about 10, respectively. As a result of the experiment, it was proved that a dielectric breakdown caused by a charge-up did not occur at all antenna ratios, which implies that a yield of product reaches 100%, which is desirable.

<Investigation of Plasma Doping Uniformity in a Wafer Surface>

The present inventor also conducted an experiment upon uniformity of ion currents in a wafer surface in the plasma doping apparatus in accordance with the present invention. An investigation result is discussed below.

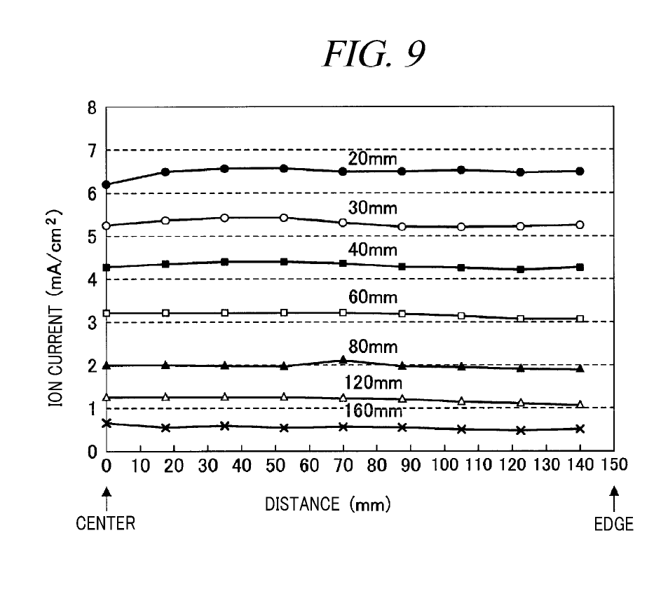

FIG. 9 is a graph showing the experiment result. The distance between the mounting table 34 and the top plate 74 was varied in the range of about 20 to about 160 mm, and an ion current at each position on a wafer was measured by a Faraday Cup for directly measuring charged particles as a current. The ion current corresponds to a dose of the impurity element.

As clearly seen from FIG. 9, when the distance between the mounting table 34 and the top plate 74 is varied in the range of about 20 to about 160 mm, the ion energy gradually increases as the distance is shortened. The ion current between the center and the edge of the wafer was maintained substantially constant at each distance. Thus, it is proved that uniformity of the ion current, i.e., the dose of the impurity element, in the wafer surface can be maintained high.

Moreover, in the above-described embodiment, although the gas feed unit 96 has the shower-head-structured doping gas feed unit 98 and the ring-shaped plasma stabilizing gas feed unit 100, their shapes are not particularly limited to those examples.

Further, although the semiconductor wafer is used as the processing target object in the above-described embodiment, the processing target object is not limited to the semiconductor wafer, but it may be a glass substrate, an LCD substrate, a ceramic substrate, or the like.

The present invention is not limited to the above-described embodiment. It would be understood by those skilled in the art that various changes and modifications may be made without departing from the scope of the invention as defined in the following claims.

The present invention is based on Japanese Patent Application Number 2007-146034, filed May 31, 2007, the entire disclosures of which are incorporated herein by reference.

### INDUSTRIAL APPLICABILITY

The present invention has many advantages when it is applied to a plasma doping apparatus and a plasma doping method.

What is claimed is:

1. A plasma doping apparatus that implants an impurity element into a surface of a processing target object by using plasma, the apparatus comprising:
a processing chamber;
a mounting table installed in the processing chamber and configured to mount the processing target object thereon;
a high frequency power supply that applies a high frequency bias power to the mounting table;
a gas feed unit that supplies a gas containing a doping gas having an impurity element into the processing chamber; and
a plasma generation unit that generates the plasma within the processing chamber.

2. The plasma doping apparatus of claim 1, wherein the plasma generation unit includes:
a planar antenna member installed outside the processing chamber;
a microwave generator that generates a microwave; and
a waveguide configured to propagate the microwave to the planar antenna member.

3. The plasma doping apparatus of claim 1, wherein the gas feed unit includes:
a doping gas feed unit that supplies the doping gas; and
a plasma stabilizing gas feed unit that supplies a plasma stabilizing gas for stabilizing the plasma.

4. The plasma doping apparatus of claim 3, wherein the doping gas feed unit has a shower head structure in which a plurality of gas discharge holes is provided at a gas flow path formed in a lattice shape.

5. The plasma doping apparatus of claim 3, wherein the plasma stabilizing gas feed unit is installed opposite to the mounting table across the doping gas feed unit.

6. The plasma doping apparatus of claim 3, wherein the plasma stabilizing gas feed unit includes a gas flow path installed along a sidewall of the processing chamber, and
the gas flow path is provided with a multitude of gas discharge holes.

7. The plasma doping apparatus of claim 1, wherein a frequency of the high frequency bias power is set to be in the range of about 400 kHz to about 13.56 MHz.

8. The plasma doping apparatus of claim 1, wherein an ion energy attracted by the high frequency bias power is set to be in the range of about 100 to about 1000 eV.

9. A plasma doping method for doping an impurity element contained in a doping gas into a surface of a processing target object, which is mounted on a mounting table within a processing chamber, by using plasma, the method comprising:
applying a high frequency bias power to the mounting table;
generating the plasma by supplying the doping gas into the processing chamber; and
doping the impurity element into the surface of the processing target object by attracting the impurity element in the doping gas by the high frequency bias power.

10. The plasma doping method of claim 9, wherein a frequency of the high frequency bias power is set to be in the range of about 400 kHz to about 13.56 MHz.

11. The plasma doping method of claim 9, wherein an ion energy attracted by the high frequency bias power is set to be in the range of about 100 to about 1000 eV.

12. The plasma doping method of claim 9, wherein an extension portion of a MOSFET is formed by doping the impurity element.

13. A storage medium that stores therein a computer-readable program for controlling an operation of a plasma doping apparatus that dopes an impurity element contained in a doping gas into a surface of a processing target object, which is mounted on a mounting table within a processing chamber, by using plasma,
wherein the computer-readable program controls the plasma doping apparatus to generate the plasma by applying a high frequency bias power to the mounting table and supplying the doping gas into the processing chamber; and to dope the impurity element into the surface of the processing target object by attracting the impurity element in the doping gas by the high frequency bias power.
